(19) United States
(12) Patent Application Publication
(10) Pub. No.: US 2012/0241905 A1
(43) Pub. Date: Sep. 27, 2012

(54) SUBSTRATE ISOLATION STRUCTURE

(76) Inventors: William W.K. Tang, Austin, TX (US); Shouli Yan, Austin, TX (US); Zhiwei Dong, Austin, TX (US)

(21) Appl. No.: 13/072,293

(22) Filed: Mar. 25, 2011

(51) Int. Cl. H01L 29/92; H01L 21/02

(52) U.S. Cl. 257/532; 438/381; 257/E29.343; 257/E21.008

(57) ABSTRACT

An integrated circuit includes a conductive substrate pick-up region in the substrate that forms a perimeter around a portion of the substrate. Conductive stripes traverse the portion of the substrate within the perimeter and are coupled to a low impedance node along with the substrate pick-up region. A capacitor has a bottom plate formed above the conductive stripes. The pick-up region and the conductive stripes absorb injected current caused by parasitic capacitance between the bottom plate of the capacitor and the substrate region thereby reducing cross-talk caused by the injected current.

### BACKGROUND

1. Field of the Invention

This application relates to current injected into a substrate and more particularly to substrate isolation structures used to address such current injection.

2. Description of the Related Art

For applications such as power conversion, e.g., an AC-DC switching power supply, there is a desire for communication links that provide high galvanic isolation. For example, such applications can require isolation between the input and output in the range of 2,500-5,000 V. Existing solutions for providing a high speed digital isolation link include the use of magnetic pulse couplers, magnetic resistive couplers, optical couplers, and capacitive couplers. FIG. 1 shows one such capacitive coupling solution. The transmitter 101 and the receiver 103 are isolated on opposite sides of a communication link 105 by capacitors 107. The capacitors 107 capacitively couple the transmitter 101 and receiver 103 to achieve galvanic isolation. Improving capacitive coupling can improve functioning of the communication link.

### SUMMARY

Accordingly, in one embodiment an integrated circuit is provided that includes a conductive pick-up region in a substrate of the integrated circuit. The conductive pick-up region forms a perimeter around a portion of the substrate within the perimeter and conductive stripes traverse the portion of the substrate within the perimeter and are coupled to a low impedance node. In an embodiment a capacitor in the integrated circuit has a bottom plate formed above the conductive stripes.

In another embodiment a method of making in integrated circuit is provided. The method includes forming a pick-up region in a substrate of an integrated circuit, the conductive pick-up region defining a perimeter around a portion of the substrate inside the perimeter. Conductive stripes are formed that traverse the portion of the substrate inside the perimeter and are coupled to a low impedance node, such as ground. The method may further include forming a bottom plate of a capacitor above the conductive stripes.

### BRIEF DESCRIPTION OF THE DRAWINGS

The present invention may be better understood, and its numerous objects, features, and advantages made apparent to those skilled in the art by referencing the accompanying drawings.

FIG. 1 illustrates a galvanic isolation solution using capacitive coupling.

FIG. 2 illustrates two pairs of differential plate-to-plate capacitors.

FIG. 3 illustrates an isolation structure using a substrate pick-up formed around a bottom plate of pairs of differential capacitors.

FIG. 4 illustrates a cross-section of an integrated circuit that includes a bottom plate of a capacitor surrounded at the substrate by substrate pick-ups and the flow of injected current through the substrate.

FIG. 5 illustrates an exemplary embodiment of the invention using stripes in the region inside of the substrate pick-up and below the capacitor.

FIG. 6 illustrates an exemplary grid pattern according to an embodiment of the invention.

FIG. 7 illustrates an exemplary grid pattern according to an embodiment of the invention.

FIG. 8 illustrates an exemplary grid pattern according to an embodiment of the invention.

FIG. 9 illustrates parasitic capacitance.

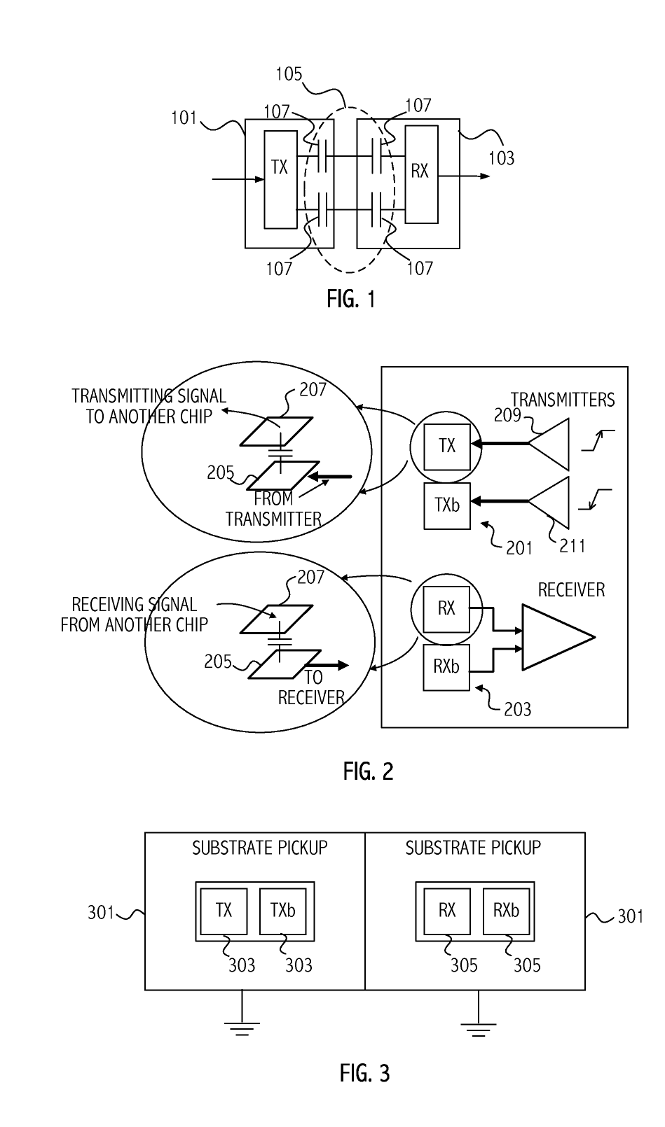

The use of the same reference symbols in different drawings indicates similar or identical items.

### DESCRIPTION OF THE PREFERRED EMBODIMENT(S)

Referring to FIG. 2, assume that there are two pairs 201 (TX and TXb) and 203 (RX and RXb) of differential plate-to-plate capacitors. Each of these capacitors includes a lower metal layer 205 forming the bottom plate, and an upper metal layer 207, forming an upper plate separated by a dielectric from the bottom plate. Assume the first pair of capacitors 201 functions as a transmitter on a communication link that is galvanically isolated from the receiver using capacitive isolation, and are driven by two output drivers 209 and 211. Each polarity (TX & TXb) swing differentially between a positive supply voltage (Vdd) and ground. The second pair of capacitors 203 functions as a receiver, receiving an external differential signal (e.g., from another chip) over the communication link.

Since these plate-to-plate capacitors are sitting on top of the substrate, the substrate can form a coupling path between two adjacent pairs of capacitors. For example, when the upper transmitter turns on, current first gets injected into the substrate through the parasitic capacitance between the bottom plate of the TX capacitor and the substrate (often called a bottom plate parasitic). The injected current can travel in all directions inside the substrate. Some of the current travels to the substrate underneath the bottom plate of an adjacent RX capacitor. That portion of the current can then get picked up by the RX capacitor through its bottom plate parasitic. When this coupled current is large enough, it can overwhelm the signal and cause a false trigger in the lower receiver. That is commonly known as cross-talk. It is therefore important to break these noise current flow paths through proper substrate isolation.

Various embodiments of this invention provide substrate isolation structures to reduce cross-talk that occurs due to injection of the electrons in the substrate. Referring to FIG. 3, one common form of isolation places a wide substrate pick-up 301 around each pair of capacitors 303 and 305. The substrate pick-up is formed as a conductive region and is typically tied to a low-impedance node (such as ground) through, e.g., vias coupled to a metal layer that is tied to ground. In that way, any electrons entering the substrate pick-up region are carried off to a ground node. The substrate pick-up provides a low impedance path to channel out part of the injected current. As a result, less injected current flows to any adjacent pair of capacitors, resulting in reduced cross-talk.

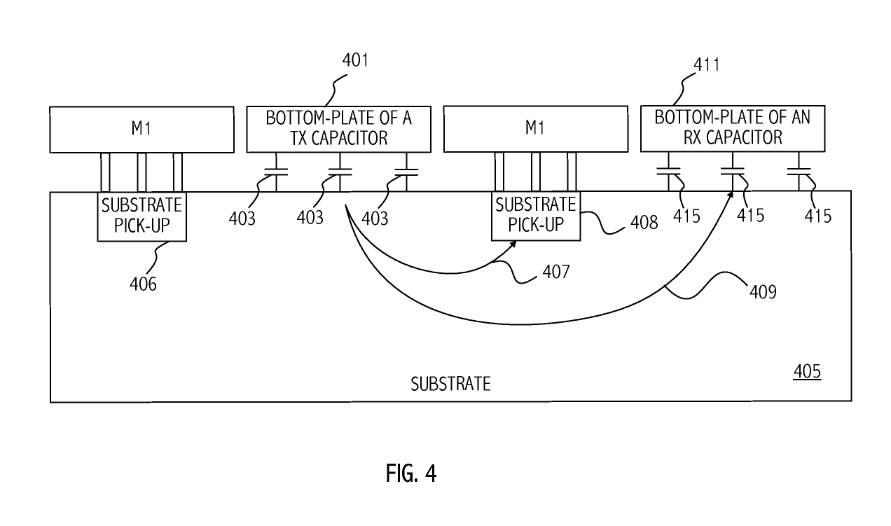

However, these plate-to-plate capacitors can be physically large. Picking up electrons injected into the substrate just around the perimeter may not provide adequate substrate isolation. FIG. 4 illustrates a portion of a cross-section of an integrated circuit that includes a bottom plate 401 of a transmit capacitor. The bottom plate is formed in the lowest metal layer M1. Bottom plate parasitic capacitance 403 formed between the bottom plate 401 and substrate 405 allows for the injection of current into the substrate 405. Current that is injected close to the center of the capacitor needs to travel a long distance before arriving at the pick-up sites (e.g., substrate pick-up 408). The current path is as shown at 407. The increased distance the current needs to travel results in increased resistance in the path that the injected current needs to travel. In turn, that increased resistance causes the injected current to travel deeper into the substrate. When that occurs, the injected current may not be easily picked up by the pick-up site. Hence, as shown at 409, injected current that escapes from the substrate pick-up 408 can propagate to the bottom plate 411 of an adjacent receiver resulting in cross-talk. That noise current is coupled to the bottom plate 411 through the parasitic capacitance 415 between the substrate 405 and the bottom plate 411 of the receive capacitor.

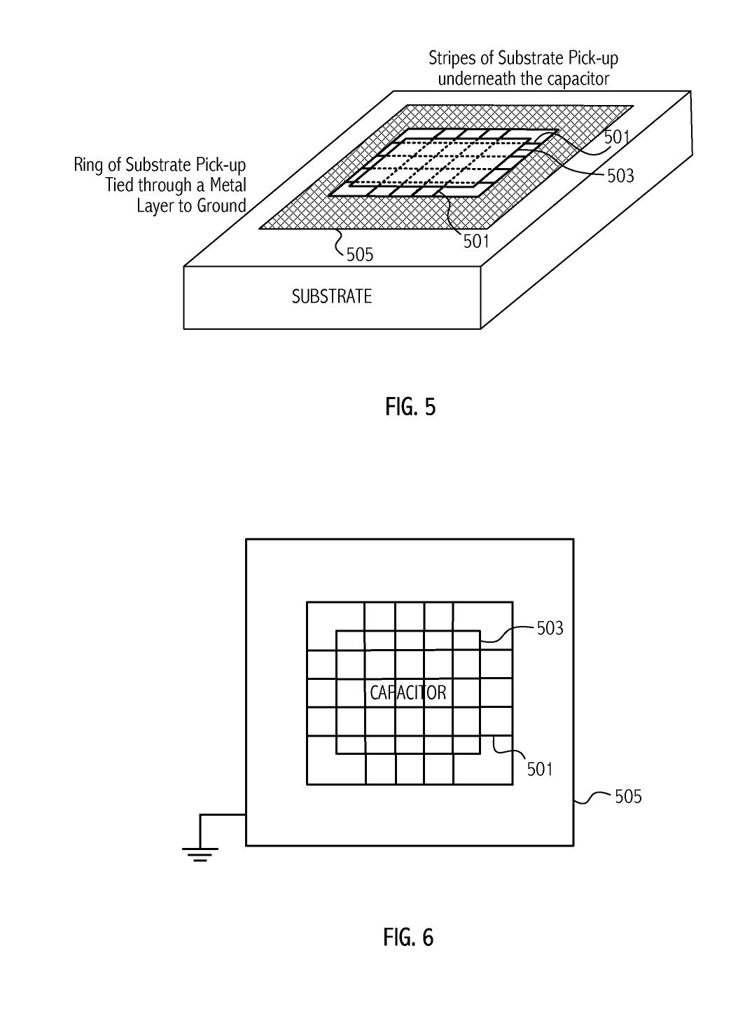

Therefore, it would be beneficial to pick up such injected current as close to the injection site as possible. Accordingly, as shown in FIG. 5, an embodiment of the invention includes conductive stripes 501 throughout the area of the bottom plate 503 of a capacitor. The conductive stripes are narrow strips of conductive material formed in the gap of the pick-up region underneath the capacitor so as to pick-up additional injected electrons. These stripes can be coupled to the substrate pickup region 505 as shown in FIG. 5 and thus can be coupled through the substrate pick-up to a low impedance node (such as ground). Alternatively, the stripes can be coupled to a low impedance node, such as ground, through another low impedance path other than through the substrate pick-up region. When an injected electron comes into contact with one of the strips of conductive material, the electron travels along the lower impedance path rather than being injected into the substrate and potentially ending up at the bottom plate of an adjacent capacitor. In FIG. 5 the portion of the stripes underneath the capacitor are shown with dotted lines. The stripes of conductive material can be formed of any suitable conductive material available in the particular semiconductor manufacturing process being used. For example, embodiments of the invention may utilize silicided polysilicon or p-active to form the stripes. Silicided polysilicon provides polysilicon with reduced resistance and similarly, p-active provides a suitable conductive material.

In embodiments the bottom plate of the capacitor is constructed with the lowest metal available (typically M1) in the manufacturing process. If on the other hand, the bottom plate of the capacitor is not constructed with the lowest metal, but instead on, e.g., M2, using either silicided polysilicon or p-active may still be desired for the stripes, as they are situated farther from the bottom plate of the capacitor. The increased separation between the stripes and the bottom plate of the capacitor reduces additional parasitic capacitance between the bottom plate of the capacitor and the stripes and between the bottom plate and the substrate. Alternatively, if M2 is used for the bottom plate, then the M1 metal layer can be used for the stripes. Stripes formed by M1 may provide better conductivity but more parasitic capacitance to the bottom plate of the capacitor on M2.

Embodiments of substrate isolation as described herein can be applied to various situations when it is important to pick up injected current in the substrate, such as the case of providing isolation between a noise source and a location where such injected current is undesirable. The plate-to-plate capacitors illustrated here are but one exemplary application where embodiments of substrate isolation structures taught herein can be used effectively to increase substrate isolation and reduce the potential for cross-talk. Other applications can also utilize isolation techniques described herein. For example, conductive stripes coupled to a low impedance node may be used to reduce noise coupling between a digital circuit area and an analog circuit area.

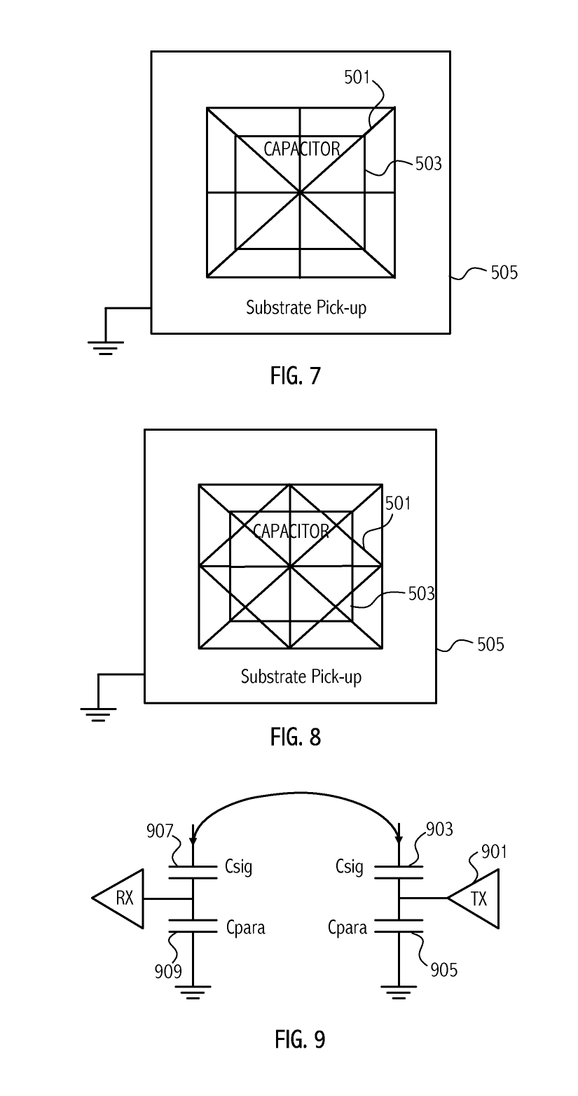

Various embodiments of stripes forming an electrical grid underneath the capacitor and extending the capability of the substrate pick-up, are shown in FIGS. 6, 7, and 8, which are views from underneath the stripes 501 looking up towards the capacitor 503. FIG. 6 illustrates another view of the grid pattern for the stripes shown in FIG. 5. FIGS. 6 and 7 show other potential embodiments of the stripes grid pattern. In FIGS. 6, 7, and 8, the stripes 501 are coupled at each end to the substrate pick-up 505, which is coupled to a ground node. Alternatively, the stripes could have their own connection to a low impedance node.

While the embodiments described in FIGS. 5-8 utilize stripes of conductive material to extend the pick-up region and reduce undesirable injected current, an alternative is to use a solid plate of substrate pick-up. However, a solid plate of substrate pick-up undesirably increases the bottom plate parasitic. Increased bottom plate parasitic capacitance can result in various undesirable effects. As illustrated in FIG. 9, one such effect is the increase in power consumption in driving the pair of capacitors on the transmit side. In addition to the amplifier 901 driving the capacitor 903, some of the amplified signal is absorbed in the parasitic capacitance 905. Another effect is the reduction in signal received by the receiver due to a larger capacitor divider ratio for capacitor 907 and the parasitic capacitance 909. Compared to using a solid plate of substrate pick-up, use of the stripes limits the degradation in the isolation effectiveness since the gap in the grid is still much smaller than the area occupied by the capacitor. Furthermore, due to their low resistance, the strips of conductive material can be made very thin, hence minimizing the parasitic capacitance between the capacitor and the substrate. For example, one embodiment may use stripes 1 μm wide in a 0.25 μm fabrication process. Still narrower widths may be used in finer fabrication process technologies. Other embodiments may utilize wider stripes. Further, various embodiments can have different density of striping. For example, in some embodiments, the stripes may be dense and cover approximately 50% of the region inside the substrate pick-up. In other embodiments the stripes may cover only 5 to 10% of the region inside the substrate pick-up. The density of the stripes in terms of width and number of stripes can be determined based on the amount of substrate isolation that is required in a particular embodiment and the amount of the parasitic capacitance a specific embodiment can tolerate.

The description of the invention set forth herein is illustrative, and is not intended to limit the scope of the invention as set forth in the following claims. Other variations and modifications of the embodiments disclosed herein may be made based on the description set forth herein, without departing from the scope and spirit of the invention as set forth in the following claims.

What is claimed is:

1. An integrated circuit comprising:
a conductive substrate pick-up region in a substrate of the integrated circuit, the conductive pick-up region forming a perimeter around a portion of the substrate within the perimeter; and
conductive stripes traversing the portion of the substrate within the perimeter, the conductive stripes coupled to a low impedance node.

2. The integrated circuit as recited in claim 1 wherein one or more of the conductive stripes are electrically coupled to the substrate pick-up region.

3. The apparatus as recited in claim 1 further comprising:
a capacitor having a bottom plate formed above the conductive stripes.

4. The integrated circuit as recited in claim 1 wherein the substrate pick-up region and the conductive stripes are electrically connected to a low impedance node.

5. The integrated circuit as recited in claim 4, wherein the low impedance node is ground.

6. The integrated circuit as recited in claim 3 wherein the bottom plate of the capacitor is formed in a lowest metal layer.

7. The integrated circuit as recited in claim 1 wherein the stripes are formed in a grid pattern.

8. The integrated circuit as recited in claim 1 wherein at least one of the stripes forms an angle other than 90 degrees with another of the stripes at their intersection.

9. The integrated circuit as recited in claim 1 wherein a density of the stripes in a horizontal plane is less than about 50%.

10. A method comprising:
forming a substrate pick-up region of conductive material in a substrate of an integrated circuit, the conductive substrate pick-up region defining a perimeter around a portion of the substrate inside the perimeter; and
forming conductive stripes that traverse the portion of the substrate inside the perimeter.

11. The method as recited in claim 10 further comprising:
forming a bottom plate of a capacitor above the conductive stripes.

12. The method as recited in claim 10 further comprising forming the conductive stripes such that the conductive stripes are connected to the substrate pick-up region.

13. The method as recited in claim 10 further comprising forming an electrical connection between the conductive stripes and a low impedance node.

14. The method as recited in claim 13, wherein the low impedance node is ground.

15. The method as recited in claim 11 further comprising forming the bottom plate of the capacitor in a lowest metal layer of the integrated circuit.

16. The method as recited in claim 10 further comprising forming the stripes in a grid pattern.

17. The method as recited in claim 10 further comprising forming at least one of the stripes so as to form an angle other than 90 degrees at an intersection of the one of the stripes and another of the stripes.

18. The method as recited in claim 10 wherein a density of the stripes is less than about 50%.

19. The method as recited in claim 10 further comprising forming the stripes of silicided poly-silicon.

20. An integrated circuit comprising:
a conductive pick-up region in a substrate of the integrated circuit, the conductive pick-up region forming a perimeter around an interior portion of the substrate;
conductive stripes coupled at each end of each stripe to the pick-up region and traversing the portion of the substrate inside the perimeter;
a transmit capacitor having a bottom plate formed above the conductive stripes;
an amplifier circuit coupled to the bottom plate to provide a signal to the bottom plate;
an output terminal coupled to a top plate of the capacitor; and
a receive capacitor having a bottom plate formed above the substrate.
